(19) United States
(12) Patent Application Publication
(10) Pub. No.: US 2011/0233715 A1
(43) Pub. Date: Sep. 29, 2011

(54) SEMICONDUCTOR DEVICE AND METHOD OF MANUFACTURING THE SAME

(75) Inventor: Atsushi NARAZAKI, Tokyo (JP)

(73) Assignee: MITSUBISHI ELECTRIC CORPORATION, Chiyoda-ku (JP)

(21) Appl. No.: 12/907,378

(22) Filed: Oct. 19, 2010

(30) Foreign Application Priority Data
Mar. 26, 2010 (JP) 2010-071246

(51) Int. Cl. H01L 29/02; H01L 21/761

(52) U.S. Cl. 257/495; 438/425; 257/E21.544; 257/E29.002

(57) ABSTRACT

A semiconductor device according to the present invention includes: a cell active region including a p-base layer being an active layer of a second conductivity type that is diffused above a high concentration n-type substrate being a semiconductor substrate of a first conductivity type; and a p-well layer being a first well region of the second conductivity type having a ring shape, which is adjacent to the p-base layer, is diffused above the high concentration n-type substrate so as to surround the cell active region, and serves as a main junction part of a guard ring structure, wherein in a region on a surface of the p-well layer other than both ends, a trench region that is a ring-shaped recess having a tapered side surface is formed along the ring shape of the p-well layer 4, the side surface widening upward.

### BACKGROUND OF THE INVENTION

1. Field of the Invention

The present invention relates to a semiconductor device and a method of manufacturing the same, and more particularly, to a termination structure of a power semiconductor element, and relates to a reduction in curvature of a diffusion layer to improve breakdown voltage performance.

2. Description of the Background Art

As semiconductor devices, in particular, power devices that are power semiconductor elements are applied to control of inverter circuits of home electrical appliances directed toward energy saving, such as air conditioners, refrigerators and washers and motors of bullet trains, subways and the like as a non-contact switch for controlling electric power. In recent years, in view of global environment, power devices have been widely applied in various fields as power devices for controlling an inverter and a converter of a hybrid car that runs with electric power and an engine and converters for photovoltaic power generation and wind power generation.

Breakdown voltage characteristics are important characteristics of power devices and, for example, the bevel structure, field plate structure, guard ring structure are typically used as a termination structure of a chip for keeping the breakdown voltage. However, in terms of the performance of holding the breakdown voltage and high reliability, the guard ring structure is used most typically among them.

In the guard ring structure, an outer periphery of an emitter region is surrounded by a belt-like ring (guard ring) of a semiconductor region of the same p-type on a surface side of a termination region of a power device chip, and each p-type semiconductor region is in a floating state. In this structure, when a positive potential is applied to a collector electrode based on an emitter electrode, a depletion layer extends from a base region side toward an outer periphery region. Then, when the depletion layer reaches the guard ring, the depletion layer extends further to reach the adjacent guard ring. As a result, the voltage (breakdown voltage) between a collector and an emitter rises depending on the number of guard rings (see Japanese Patent Application Laid-Open No. 08-306937).

In order to stabilize the breakdown voltage to reduce losses due to the generation of leakage current, optimum guard ring intervals are required. Larger intervals between guard rings impose a limit on extension of the depletion layer, and a strong electric field region is generated in the p-type semiconductor region, which causes a drop in breakdown voltage (VCES) and a rise in leakage current (ICES). On the other hand, smaller intervals between guard rings cause quick punch-through of the depletion layer to the channel stopper part, and thus the leakage current is stabilized, which unfortunately causes a drop in breakdown voltage.

Further, the termination region such a guard ring is outside the cell activation region of a chip, and thus the point is how to reduce an area of the termination region outside the activation region (that is, how to shrink a termination) for reducing a chip cost. However, there is a fear that a reduction in the number of guard rings for reducing an area may cause a drop in breakdown voltage and an increase in leakage current. Accordingly, for shrinking the termination region, it is effective to reduce an area per guard ring or to raise a voltage for each guard ring.

Here, when an area per guard ring (diffusion formation width of a p-layer) is reduced, the diffusion layer cannot be formed to be deep, and a curvature of the diffusion layer reduces. On the other hand, in order to increase the voltage for each guard ring, it is required to increase a curvature of the diffusion layer to relax an electric field, which is unfortunately difficult in a case of reducing an area per guard ring.

### SUMMARY OF THE INVENTION

An object of the present invention is to provide a semiconductor device that shrinks a termination region while keeping a high breakdown voltage, and a method of manufacturing the same.

A semiconductor device according to the present invention includes: a cell active region including an active layer of a second conductivity type diffused above a semiconductor substrate of a first conductivity type; and a first well region of the second conductivity type having a ring shape, which is adjacent to the active layer, is diffused above the semiconductor substrate so as to surround the cell active region, and serves as a main junction part of a guard ring structure. In a region on a surface of the first well region other than both ends, a ring-shaped recess having a tapered side surface is formed along the ring shape of the first well region, the side surface widening upward.

According to the semiconductor device of the present invention, the curvature of the first well region is reduced, whereby it is possible to shrink a termination region while keeping a high breakdown voltage.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device according to a first preferred embodiment;

FIGS. 2 to 5 are views showing a processing flow of the semiconductor device according to the first preferred embodiment;

FIG. 6 is a cross-sectional view of a p-well layer of the semiconductor device according to the first preferred embodiment;

FIG. 7 is a cross-sectional view of the semiconductor device according to the first preferred embodiment;

FIG. 8 is a cross-sectional view of the semiconductor device according to the first preferred embodiment, which is applied to a guard ring structure;

FIG. 9 is a cross-sectional view of a semiconductor device according to a second preferred embodiment;

FIGS. 10 to 13 are views showing a processing flow of a semiconductor device according to a third preferred embodiment;

FIGS. 14 and 15 are cross-sectional views of a conventional semiconductor device;

FIG. 16 is a top view of the conventional semiconductor device;

FIG. 17 is a graph showing a breakdown voltage value of the conventional semiconductor device;

FIGS. 18A and 18B are cross-sectional views of the conventional semiconductor device; and

FIG. 19 is a perspective view of the conventional semiconductor device.

### DESCRIPTION OF THE PREFERRED EMBODIMENTS

For comparison, a conventional guard ring structure is descried below. In particular, as to the conventional case, description is given of a p-well region that is a main junction part of the guard ring structure.

FIG. 14 is a cross-sectional view of a termination region of a conventional power device chip, which shows a PN junction structure. Here, the structure of a diode is described as an example of a device. For the sake of convenience, a channel stopper region and a scribe line are omitted.

A p-base layer 103 is formed through diffusion on a surface of a low concentration n-type drift layer 102 formed on a high concentration n-type substrate 101, and a p-well layer 104 is formed so as to surround the p-base layer 103. As shown in FIG. 14, the p-well layer 104 has radius of curvature portions 112 and 113 at a boundary between the low concentration n-type drift layer 102 and itself.

An interlayer insulating film 105 is formed on main surfaces thereof except for part of a surface on the p-base layer 103, and an anode contact 106 for connection with the p-base layer 103 is formed on the surface on which the interlayer insulating film 105 is not formed. The anode contact 106 is formed so as to cover part of the interlayer insulating film 105.

An anode electrode 107 is connected to the p-base layer 103 through the anode contact 106. Further, an overcoat protective film 108 is coated on an upper surface of the anode contact 106 and is formed so as to cover the interlayer insulating film 105 and the anode contact 106.

A positive bias is applied to a cathode electrode 116 connected to the back surface with the anode electrode 107 being the ground, whereby a depletion layer 109 extends from the p-well layer 104 toward the termination region. The extending distance of the depletion layer 109 is dependent on the voltage to be applied, and thus the distance of the depletion layer 109 extending toward the termination region becomes longer as a voltage rises. FIG. 14 shows the depletion layer 109 in a state of being applied with a voltage.

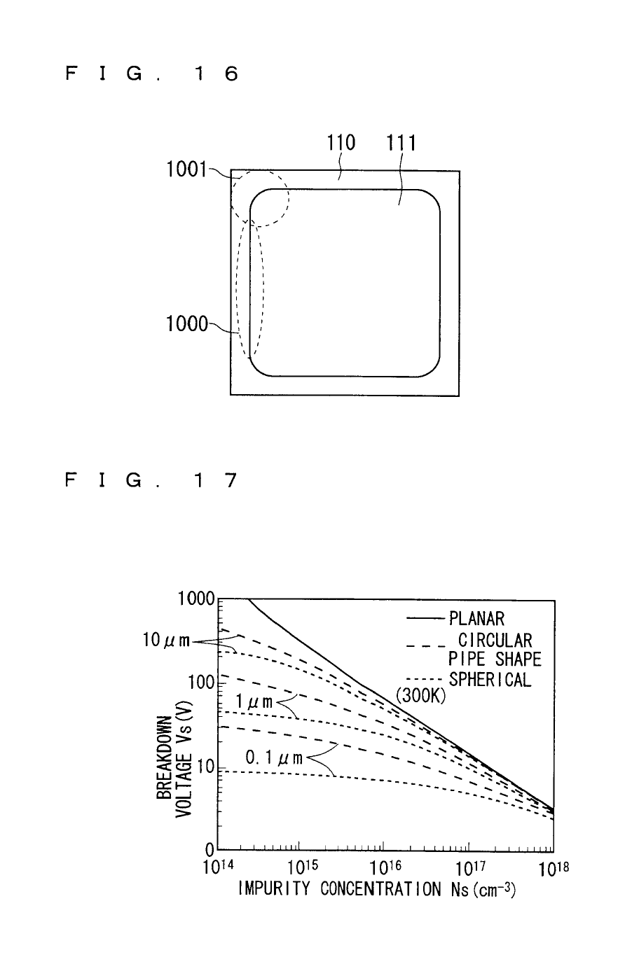

FIG. 15 is an enlarged view of the p-well layer 104 and the radius of curvature portions 112 and 113 shown in FIG. 14. It is possible to obtain a desired diffusion depth in the p-well layer 104 by, for example, implanting boron and then performing drive processing. In this case, a radius of curvature r1 of the p-well layer 104 in cross section can be set small in a case of a small diffusion depth, whereas the radius of curvature r1 can be set large in a case of a large diffusion depth.

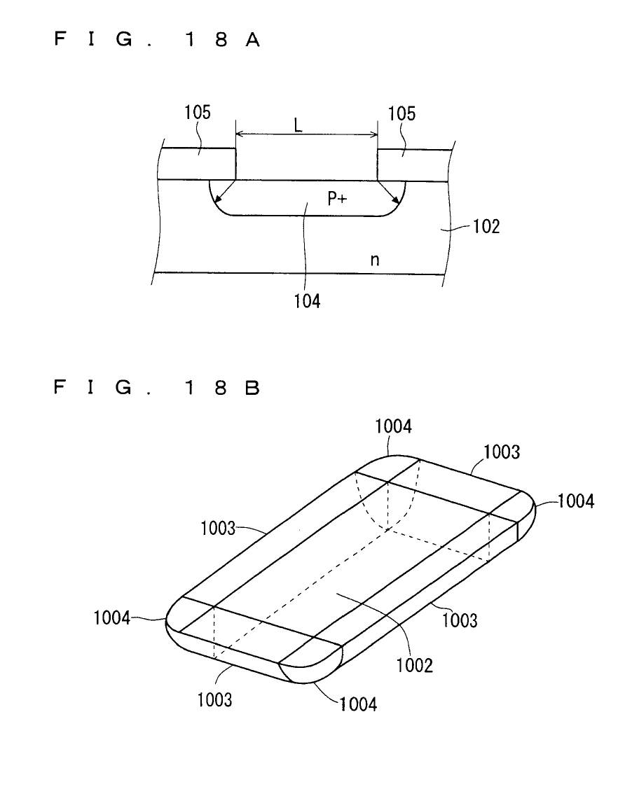

FIGS. 16 and 17 show an effect of the radius of curvature (corresponding to radius of curvature portions 112 and 113) of the p-well layer 104 shown in FIG. 15 on the breakdown voltage value.

FIG. 16 briefly shows a diode chip viewed from above, in which an anode p-type semiconductor layer 111 is formed in an n-type semiconductor layer 110.

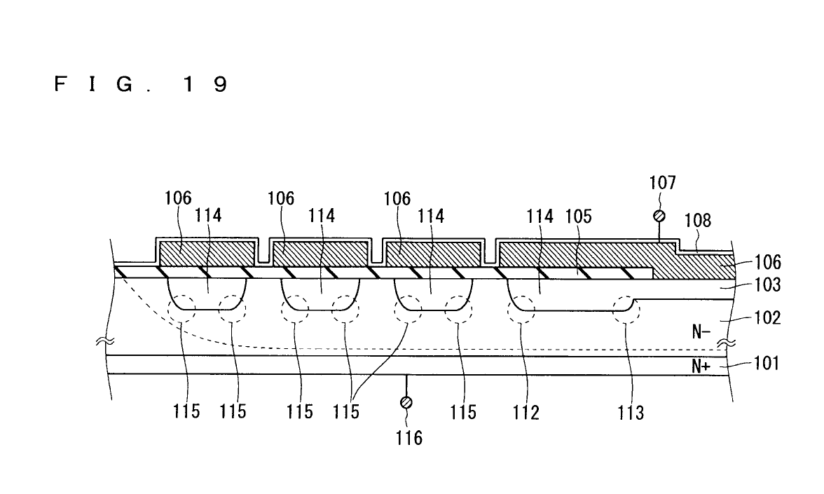

A cylindrical structure 1000 and a spherical structure 1001 are provided in a bonding region of the n-type semiconductor layer 110 and the anode p-type semiconductor layer 111 as shown in FIG. 16, and a breakdown voltage drops as a radius of curvature of each structure becomes smaller. As shown in FIG. 18B, a breakdown voltage drops as a radius of curvature of each structure becomes smaller also in a case where a planar region 1002, a circular pipe region 1003 and a spherical region 1004 are provided. FIG. 17 shows breakdown voltages of planar, circular-pipe-shaped and spherical structures when the radius of curvature is 10 μm, 1 μm and 0.1 μm in a case of FIG. 18B, in which the breakdown voltage drops as the radius of curvature becomes smaller when the impurity concentration is approximately the same. Here, a vertical axis and a horizontal axis of FIG. 17 represent breakdown voltage and impurity concentration, respectively.

During voltage application, the radius of curvature portion 112 or the radius of curvature portion 113 of the p-well layer 104 of FIG. 15 has an electric field peak and, breakdown occurs due to avalanche breakdown at the time when the electric field reaches a critical electric field of, for example, 2×10⁵ cm/V or more.

With a structure of a conventional p-well region, a ratio of a horizontal diffusion/vertical diffusion (XY ratio) is generally 0.8 as shown in FIG. 18A, and thus in a case where, for example, boron that is a p-type impurity is diffused for 5 μm in a vertical direction in cross section, boron is diffused for 4 μm in a horizontal direction therein.

FIG. 19 shows an application of a conventional guard ring structure. This guard ring structure has, in addition to the p-well layer 104 adjacent to the p-base layer 103, p-well layers 114 and radius of curvature portions 115 formed at a boundary between the low concentration n-type drift layer 102 and the p-well layer 114 that is a floating p-type diffusion region.

According to the conventional technology described above, the problems described in BACKGROUND OF INVENTION cannot be solved. Preferred embodiments of the present invention to solve the above-mentioned problems are described below.

### A. First Preferred Embodiment

### A-1. Configuration

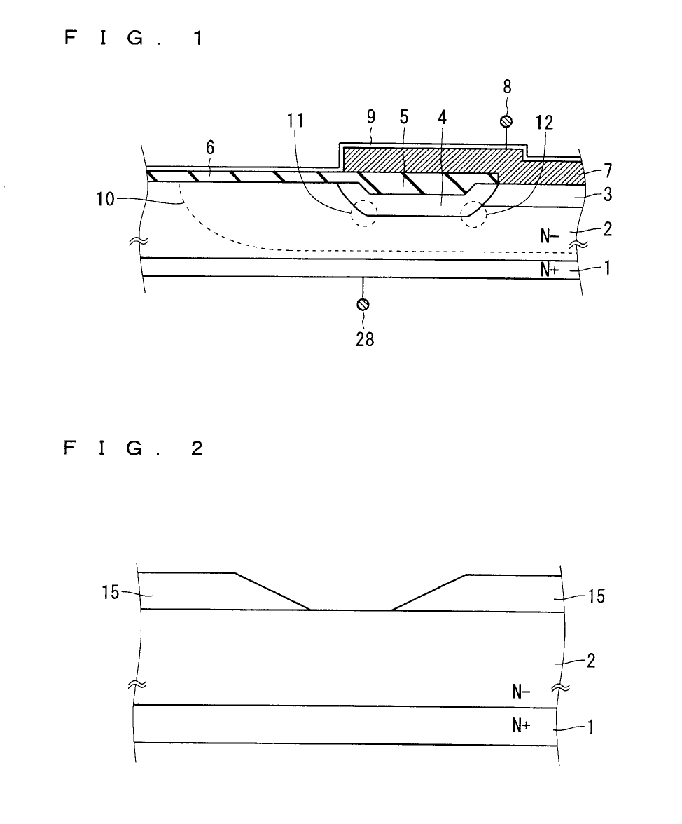

FIG. 1 is a cross-sectional view of a termination region of a power device chip according to the present invention, which shows a PN junction structure. Herein, description is given of the structure of a diode as a device example. For the sake of convenience, a channel stopper region and a scribe line are omitted.

A p-base layer 3 serving as an active layer is formed through diffusion on a surface of a low concentration n-type drift layer 2 formed (epitaxially grown) on a high concentration n-type substrate 1, and a p-well layer 4 serving as a first well region is formed so as to surround a cell active region (in this preferred embodiment, a diode in formed therein) including the p-base layer 3. The p-well layer 4 is a main junction part of the guard ring structure, which is adjacent to the p-base layer 3 and is diffused in a ring shape. Further, in the p-well layer 4, formed along a ring shape thereof is a trench region 5 (sink region) that is a ring-shaped recess whose side surface has a tapered shape in which the side surface widens upward.

An interlayer insulating film 6 is formed on main surfaces thereof except for part of the surface on the p-base layer 3, and an anode contact 7 for connecting to the p-base layer 3 is formed on the surface on which the interlayer insulating film 6 is not formed. The anode contact 7 is formed so as to partially cover the interlayer insulating film 6.

An anode electrode 8 is connected to the p-base layer 3 through the anode contact 7. Further, an overcoat protective film 9 is coated on an upper surface of the anode contact 7 and is formed so as to cover the interlayer insulating film 6 and the anode contact 7.

A positive bias is applied to a cathode electrode 28 connected to a back surface with the anode electrode 8 being the ground, whereby a depletion layer 10 extends from the p-well layer 4 toward the termination region. FIG. 1 shows the depletion layer 10 in a case where a voltage is applied.

When a voltage is applied, a radius of curvature portion 11 or a radius of curvature portion 12 of the p-well layer 4 has an electric field peak, and breakdown occurs due to avalanche breakdown at the time when an electric field reaches critical electric field of, for example, 2×10⁵ cm/V or more. However, as shown in FIG. 1, the radius of curvature portions 11 and 12 are designed so as to have larger curvature radii than those of the radius of curvature portions 112 and 113 shown in FIG. 14, and thus the voltage reaching a critical voltage becomes higher compared with a conventional structure. That is, it is possible to keep the peak electric field low even at the same voltage.

### A-2. Manufacturing Method

Here, a flow chart of manufacturing the semiconductor device according to the present invention is described. First, as shown in FIG. 2, the low concentration n-type drift layer 2 is formed on the high concentration n-type substrate 1, and then a pattern for forming the p-well layer 4 is formed with a photoresist 15 serving as a mask having a tapered shape at an end thereof. Here, the photoresist 15 extends from a region except for the region to be the p-well layer 4 toward part of the region to be the p-well layer 4.

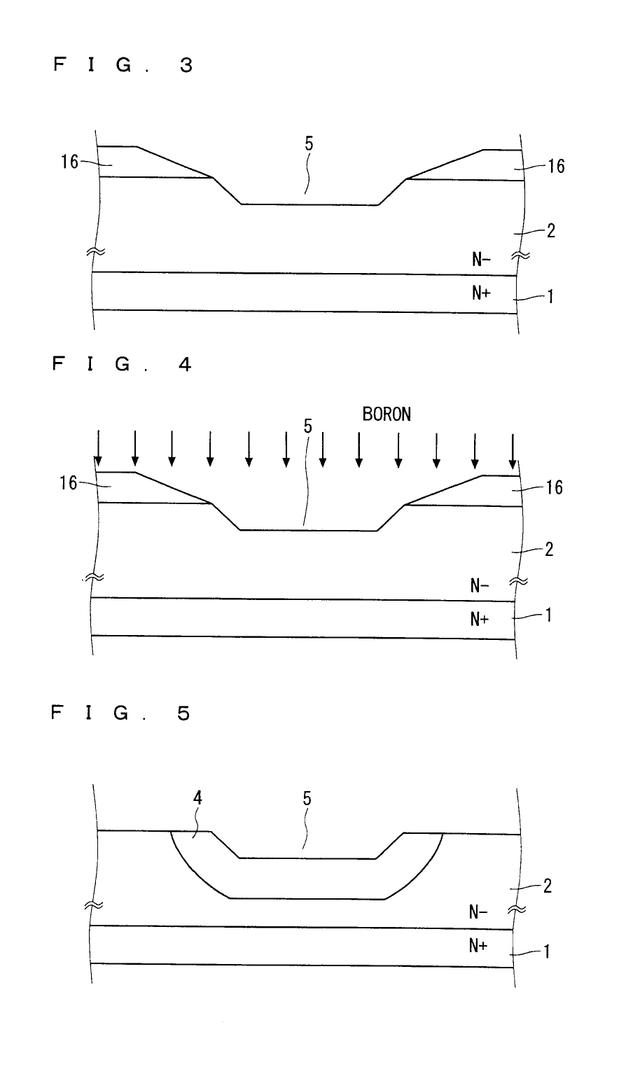

Then, as shown in FIG. 3, the low concentration n-type drift layer 2 is etched to a target depth using dry etching. In this case, a tapered shape is formed in advance in the photoresist 15 serving as a mask as described above, and the photoresist 15 is further subjected to etching with a small selection ratio. Accordingly, after the etching process, the trench region 5 that is a recess having a tapered shape on its side surface is formed as shown in FIG. 3. Note that a target of the etching depth is 1.5 μm in this case. Note that the photoresist 15 is also etched by this etching process, which becomes a photoresist 16.

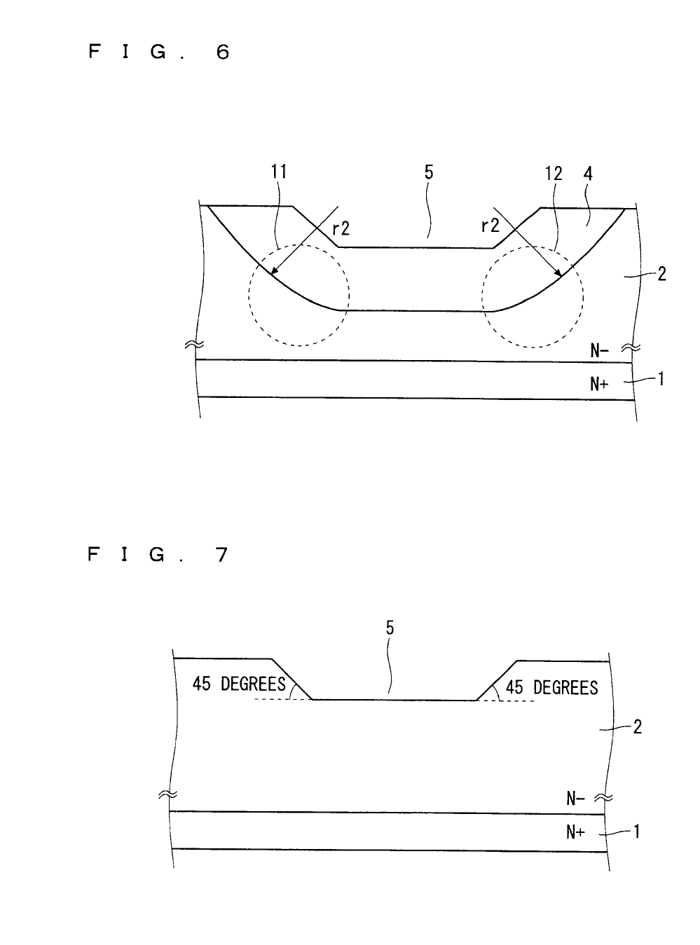

Then, as shown in FIG. 4, boron that is a p-type impurity is implanted into an entire surface of a substrate with the photoresist 16 being a mask, and drive processing is performed after the photoresist 16 is removed, with the result that the p-well layer 4 having a desired diffusion shape is obtained (FIG. 5).

Here, description is given of dry etching (etching with small selection ratio of Si) using the photoresist 15 for obtaining the trench region 5 having a tapered shape.

Generally, an ECR etcher is capable of obtaining plasma of relatively high density in a low pressure region of etching equipment. When a large amount of chlorine radicals and fluorine radicals that are chemically active are produced in plasma of high density, they hardly react with the resist while keeping high reactivity with Si, whereby high selection ratio can be obtained.

If the RF power is excessively increased on this occasion, charged particles physically impinge on the resist, whereby film reduction occurs in the resist and an oxide film, leading to a reduction in selection ratio. Therefore, the RF power has been used at 0 to 50 W in, for example, etchback of poly-Si.

On the other hand, in a case where a semiconductor device according to the present invention is manufactured, etching with low selection ratio is required. Accordingly, Ar is added as a material for charged particles, and the RF power is increased, to thereby reduce a selection ratio of resist.

In this case, Ar of charged particles and ion physically impinge on the resist, and hydrocarbon molecules that are the material for resist are once separated from the resist. After that, the hydrocarbon molecules adhere to a wafer and a chamber again, leading to an excessive deposition state. In order to avoid this state, an appropriate amount of O₂ is added, and oxidation is performed before readhesion of hydrocarbon molecules so as to be vaporized as CO₂.

One example of etching conditions in this case are as follows.

Gas flow rate: Ar/SF₆/Cl₂/O₂=50/30/30/20 ccm (SF₆/Cl₂=30/30 ccm)

Processing pressure: 0.8 Pa

Magnetron power: 400 W

RF power: 100 W

A film thickness of the resist is 5.7 μm before etching and 4.2 μm after etching. That is, the trench region 5 having a tapered shape is formed at a selection ratio of 1:1.

FIG. 6 shows a diffusion shape of the p-well layer 4 after being processed in accordance with the processing flow. As shown in FIG. 4, by implanting and diffusing into the trench region 5 having a tapered shape, the radius of curvature portion 11 and the radius of curvature portion 12 having a more smooth diffusion shape are obtained compared with a case where implantation and diffusion are performed into a flat surface. Accordingly, a radius of curvature r2 can also be set to be larger than a radius of curvature r1 of a conventional structure (see FIG. 15).

Therefore, an electric field of the radius of curvature portion 11 or the radius of curvature portion 12 of the p-well layer 4 can be reduced, leading to improvements in breakdown voltage.

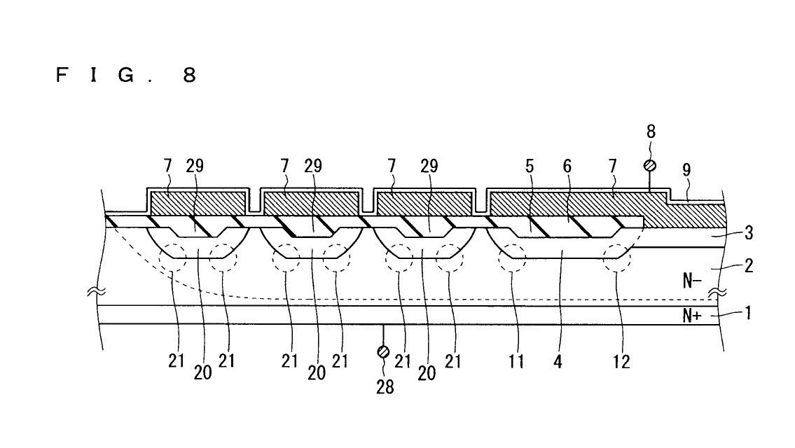

An angle of a tapered shape in the trench region 5 is set to, for example, 45 degrees or less as shown in FIG. 7, with the result that an effect of reducing a curvature of a diffusion layer is enhanced and the breakdown voltage is improved.

In the first preferred embodiment, while the description is given of the structure using an epi wafer, the epi wafer is unable to have high breakdown voltage, and it is costly to manufacture a wafer. Accordingly, the structure using a floating zone (FZ) can be used as well. Also in this case, similar effects are achieved and breakdown voltage as well as cost thereof can be reduced further.

Further, while the application to the diode device is described in the first preferred embodiment, similar effects are achieved also in an insulated gate bipolar transistor (IGBT) device. In addition, similar effects are achieved in a metal oxide semiconductor field effect transistor (MOSFET) device and a device using an Si carbide expected to have high efficiency, which has been developed in recent years.

Further, while the concentration of PN junction is not particularly specified in the first preferred embodiment, similar effects are achieved and an effect of relaxing an electric field is enhanced by setting the concentration to have a P/N concentration ratio so as to obtain RESURF conditions. Accordingly, a termination can be further applied to a shrink structure.

### A-3. Application

FIG. 8 shows an application of the guard ring structure according to the present invention. In this guard ring structure, in addition to the p-well layer 4 adjacent to the p-base layer 3, there are provided p-well layers 20 that surround the p-well layer 4 apart from the p-well layer 4 and individually serve as a second well region being a floating p-type diffusion region. The p-well layer 20 has a trench region 29 that is a recess and radius of curvature portions 21 formed at a boundary between the low concentration n-type drift layer 2 and itself. The trench region 29 is formed along a ring shape of the p-well layer 20, and has a tapered side surface in which the side surface widens upward. The voltage per guard ring can be set large by making a radius of curvature of the radius of curvature portion 21 larger than that of the conventional guard ring structure. Therefore, it is possible to reduce the number of guard rings (p-well layers 20), whereby a termination region can be shrunk.

Note that effects of the present invention are achieved if a semiconductor has opposite conductivity types.

### A-4. Effects

According to the first preferred embodiment of the present invention, the semiconductor device includes: the cell active region including the p-base layer 3 that is an active layer of a second conductivity type diffused above the high concentration n-type semiconductor substrate 1 that is a semiconductor substrate of a first conductivity type; and the p-well layer 4 as a first-well region of the second conductivity type having a ring shape, which is adjacent to the p-base layer 3, is diffused above the high concentration n-type substrate 1 so as to surround the cell active region, and serves as a main junction part of a guard ring structure, wherein in a region on a surface of the p-well layer 4 other than both ends, the trench region 5 that is a ring-shaped recess having a tapered side surface is formed along the ring shape of the p-well layer 4, the side surface widening upward. Accordingly, the curvature of the p-well layer 4 is reduced, and thus it is possible to shrink a termination region while keeping a high breakdown voltage.

Further, according to the first preferred embodiment of the present invention, the semiconductor device further includes the floating second p-well layer 20 of the second conductivity type being the second well region that is diffused above the high concentration n-type semiconductor substrate 1 being a semiconductor substrate so as to surround the p-well layer 4, apart from the p-well layer 4 as the first well region, wherein in the region on the surface of the p-well layer 20 other than both ends, the trench region 29 that is a ring-shaped recess having a tapered side surface is formed along the ring shape of the p-well layer 20, the side surface widening upward. Accordingly, the guard ring structure is further formed, which makes it possible to achieve higher breakdown voltage.

Further, according to the first preferred embodiment of the present invention, in the semiconductor device, the trench region 5 that is a recess has an inclination angle of 45 degrees or less on the side surface thereof. Accordingly, the curvature of the p-well layer 4 is reduced further, and an effect of relaxing an electric field is improved, leading to an improvement in breakdown voltage.

Further, according to the first preferred embodiment of the present invention, in the semiconductor device, the high concentration n-type substrate 1 being a semiconductor substrate is a semiconductor substrate containing an impurity of the first conductivity type that is manufactured by the FZ method. Accordingly, higher breakdown voltage and lower cost can be achieved.

Further, according to the first preferred embodiment of the present invention, a method of manufacturing a semiconductor device includes the steps of: (a) forming the cell active region including the p-base layer 3 that is an active layer of a second conductivity type diffused above the high concentration n-type substrate 1 that is a semiconductor substrate of the first conductivity type; (b) forming the p-well layer 4 that is a first well region of the second conductivity type having a ring shape, the forming p-well layer 4 being adjacent to the p-base layer 3, being diffused above the high concentration n-type semiconductor substrate 1 so as to surround the cell active region, and serving as a main junction part of a guard ring structure; and (c) forming, prior to the step (b), the trench region 5 that is a ring-shaped recess having a tapered side surface along the ring shape of the p-well layer 4 in a region on the surface of the p-well layer 4 other than both ends, the side surface widening upward. Accordingly, the curvature of the p-well layer 4 is reduced, which makes it possible to shrink the termination region while keeping a high breakdown voltage.

Further, according to the first preferred embodiment of the present invention, in the method of manufacturing a semiconductor device, the step (c) forming, prior to the step (b), the trench region 5 that is a ring-shaped recess having a tapered side surface along the ring shape of the p-well layer 4 in a region on the surface of the p-well layer 4 other than both ends, the side surface widening upward, includes the steps of: (c-1) forming the photoresist 15 that is a mask extending from a region other than the p-well layer 4 to part of the p-well layer 4 and having a tapered shape at ends thereof; and (c-2) etching the high concentration n-type substrate 1 that is a semiconductor substrate through the photoresist 15 to form the trench region 5. Accordingly, the curvature of the p-well layer 4 is reduced, which makes it possible to shrink the termination region while keeping a high breakdown voltage.

### B. Second Preferred Embodiment

### B-1. Configuration

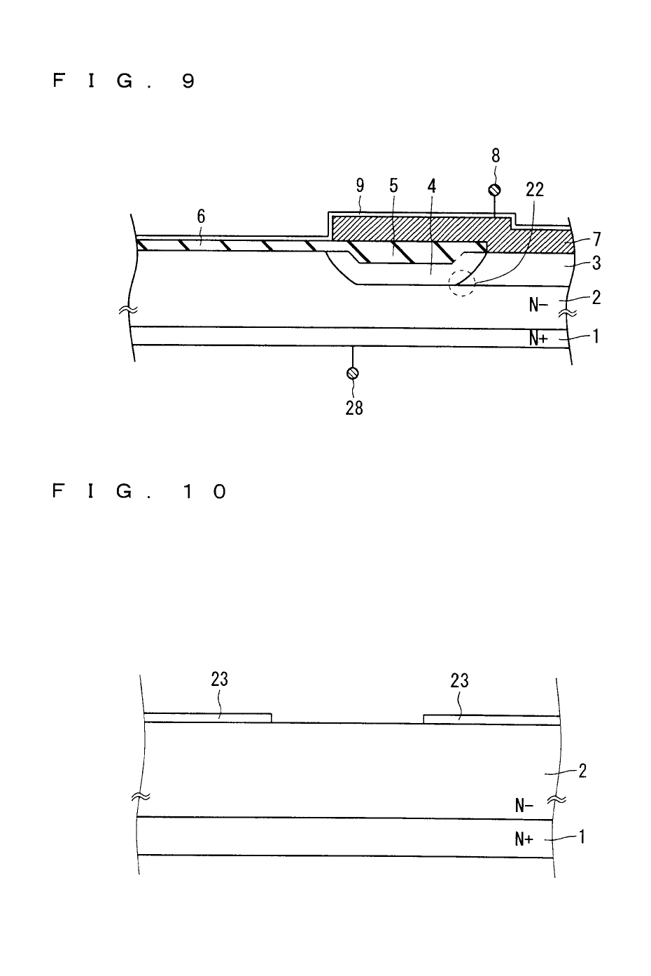

While the diffusion depth of the p-base layer 3 is smaller than the diffusion depth of the p-well layer 4 in the first preferred embodiment, as shown in FIG. 9, both depths can be set equal to each other. The other configuration is similar to that of the first preferred embodiment, and thus detailed description thereof is omitted.

### B-2. Operation

The p-base layer 3 and the p-well layer 4 are formed as descried above, and thus an electric field is not concentrated on one of radius of curvature portions 22 of the p-well layer 4, and breakdown is unlikely to occur due to avalanche breakdown in the radius of curvature portion 22. Accordingly, the breakdown voltage can be improved further.

### B-3. Effects

According to the second preferred embodiment of the present invention, in the semiconductor device, the p-base layer 3 that is an active layer and the p-well layer 4 that is a first well region are equal in diffusion depth above the high concentration n-type substrate 1 that is a semiconductor substrate. Accordingly, an electric field is not concentrated on one of the radius of curvature portions 22 of the p-well layer 4, which further improves the breakdown voltage.

### C. Third Preferred Embodiment

### C-1. Manufacturing Method

While the trench region 5 having a tapered shape is formed by dry etching in the first preferred embodiment, as shown in the flow of FIGS. 10 to 13, it may be formed through a flow of local oxidation of silicon (LOCOS) oxidation.

The flow of LOCOS oxidation is described below. As shown in FIG. 10, first, the low concentration n-type drift layer 2 is formed on the high concentration n-type substrate 1, and then, a pattern for forming the p-well layer 4 is formed on the low concentration n-type drift layer 2 using a nitride film 23. The nitride film 23 is formed in a region other than the region to be the p-well layer 4.

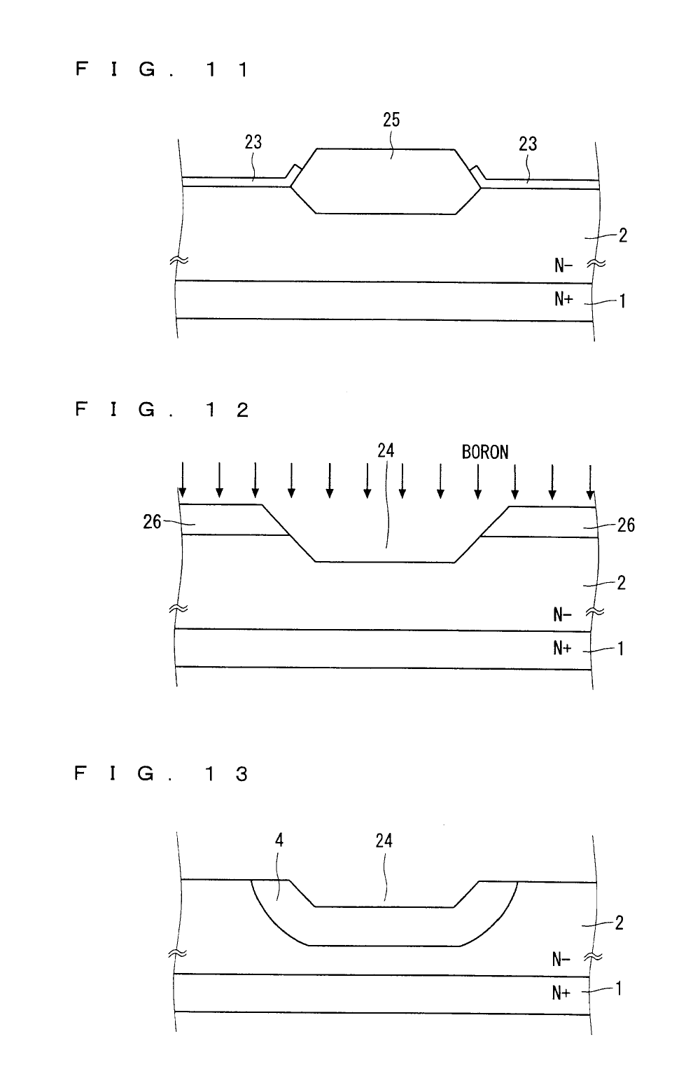

Then, as shown in FIG. 11, a LOCOS oxide film 25 is formed by LOCOS oxidation. Then, as shown in FIG. 12, the nitride film 23 and the LOCOS oxide film 25 are removed, and a photoresist 26 is formed so as to make the pattern to be the p-well layer 4 open. In this case, a trench region 24 that is a recess having a tapered shape on its side surface is formed in the part in which the LOCOS oxide film 25 is removed. After that, boron that is a p-type impurity is implanted into the entire surface of the substrate.

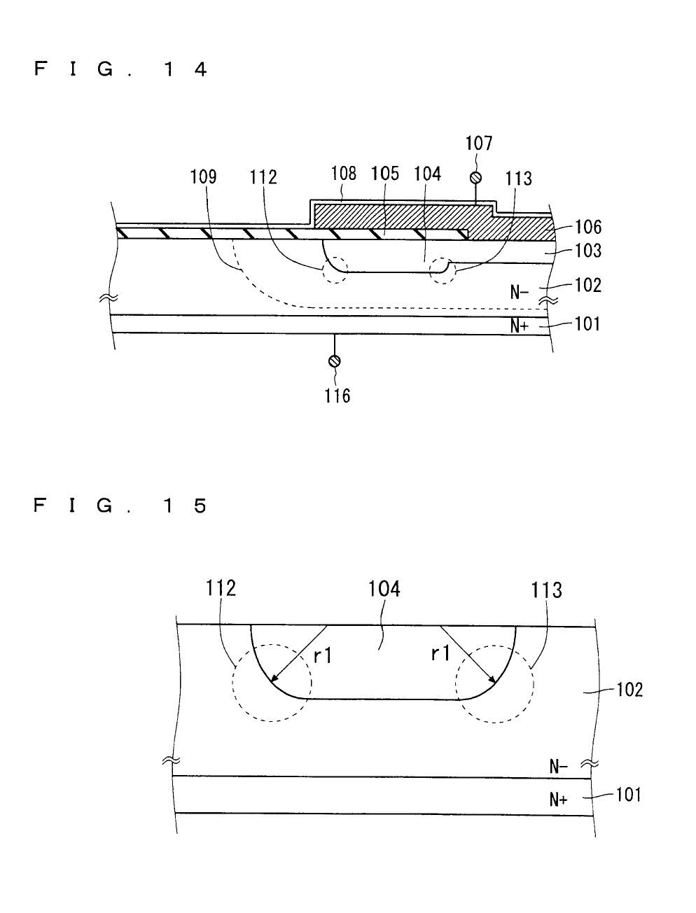

After that, as shown in FIG. 13, the photoresist 26 is removed, and then drive processing is performed, with the result that the p-well layer 4 having a desired diffusion shape is obtained.

### C-2. Effects

According to the third preferred embodiment of the present invention, in the method of manufacturing a semiconductor device, prior to the step (b) of forming the p-well layer 4 that is a first well region of the second conductivity type having a ring shape, the first well region being adjacent to the p-base layer 3, being diffused above the high concentration n-type semiconductor substrate 1 so as to surround the cell active region, and serving as a main junction part of a guard ring structure, the step (c) of forming the trench region 5 that is a ring-shaped recess having a tapered side surface along the ring shape of the p-well layer 4 in a region on the surface of the p-well layer 4 other than both ends, the side surface widening upward, includes the steps of: (c-1) forming the nitride film 23 in a region other than the p-well layer 4; and (c-2) subjecting the high concentration n-type substrate 1 that is a semiconductor substrate to LOCOS oxidation through the nitride film 23, and removing the formed LOCOS oxide film 25 and nitride film 23 to form the trench region 24 that is a recess. Accordingly, the curvature of the p-well layer 4 is reduced, which makes it possible to shrink a termination region while keeping a high breakdown voltage. Moreover, damage from etching will not occur, which leads to stable breakdown voltage characteristics.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a cell active region including an active layer of a second conductivity type diffused above a semiconductor substrate of a first conductivity type; and
a first well region of the second conductivity type having a ring shape, which is adjacent to said active layer, is diffused above said semiconductor substrate so as to surround said cell active region, and serves as a main junction part of a guard ring structure,
wherein in a region on a surface of said first well region other than both ends, a ring-shaped recess having a tapered side surface is formed along the ring shape of said first well region, the side surface widening upward.

2. The semiconductor device according to claim 1, further comprising a floating second well region of the second conductivity type diffused above said semiconductor substrate so as to surround said first well region, apart from said first well region,
wherein in a region on a surface of said second well region other than both ends, a ring-shaped recess having a tapered side surface is formed along the ring shape of said second well region, the side surface widening upward.

3. The semiconductor device according to claim 1, wherein said active layer and said first well region are equal in diffusion depth above said semiconductor substrate.

4. The semiconductor device according to claim 1, wherein said recess has an inclination angle of 45 degrees or less on the side surface thereof.

5. The semiconductor device according to claim 1, wherein said semiconductor substrate is a semiconductor substrate containing an impurity of the first conductivity type manufactured by an FZ method.

6. A method of manufacturing a semiconductor device, comprising the steps of:
(a) forming a cell active region including an active layer of a second conductivity type diffused above a semiconductor substrate of a first conductivity type;
(b) forming a first well region of the second conductivity type having a ring shape, the first well region being adjacent to said active layer, being diffused above said semiconductor substrate so as to surround said cell active region, and serving as a main junction part of a guard ring structure; and
(c) forming, prior to said step (b), a ring-shaped recess having a tapered side surface along the ring shape of said first well region in a region on a surface of said first well region other than both ends, the side surface widening upward.

7. The method of manufacturing a semiconductor device according to claim 6, wherein said step (c) comprises the steps of:
(c-1) forming a mask extending from a region other than said first well region to part of said first well region and having a tapered shape at ends thereof; and
(c-2) etching said semiconductor substrate through said mask to form said recess.

8. The method of manufacturing a semiconductor device according to claim 6, wherein said step (c) comprises the steps of:
(c-1) forming a nitride film in a region other than said first well region; and
(c-2) subjecting said semiconductor substrate to LOCOS oxidation through said nitride film, and removing a LOCOS oxide film formed by said LOCOS oxidation and said nitride film to form said recess.
